(19) United States
(12) Patent Application Publication
(10) Pub. No.: US 2025/0072223 A1
(43) Pub. Date: Feb. 27, 2025

(54) DISPLAY DEVICE AND METHOD FOR FABRICATING THE SAME

(71) Applicant: Samsung Display Co., LTD., Yongin-si (KR)

(72) Inventors: Seung Bae KANG, Yongin-si (KR); Moo Soon KO, Yongin-si (KR); Sung Jun KIM, Yongin-si (KR); Seung Gyu TAE, Yongin-si (KR)

(21) Appl. No.: 18/657,995

(22) Filed: May 8, 2024

(30) Foreign Application Priority Data
Aug. 21, 2023 (KR) 10-2023-0108896

(51) Int. Cl. H10K 59/122; H10K 59/12; H10K 59/124

(52) U.S. Cl. CPC H10K 59/122; H10K 59/1201; H10K 59/124

(57) ABSTRACT

A display device includes: a substrate; a transistor on the substrate; an interlayer insulating layer on the transistor; a first electrode disposed on the interlayer insulating layer and connected to the transistor through a contact hole in the interlayer insulating layer; a pixel defining layer disposed on the interlayer insulating layer and the first electrode; a sacrificial layer disposed in a groove of the interlayer insulating layer; a gap fill layer disposed on the sacrificial layer, between a first sub-pixel defining layer and a second sub-pixel defining layer included in the pixel defining layer; a light emitting stack on the first electrode and the pixel defining layer; and a first trench formed between the first sub-pixel defining layer and the gap fill layer, between an inner wall of the groove and the gap fill layer, and between the inner wall of the groove and the sacrificial layer.

This application claims priority to Korean Patent Application No. 10-2023-0108896 filed on Aug. 21, 2023, and all the benefits accruing therefrom under 35 U.S.C. § 119, the content of which in its entirety is herein incorporated by reference.

### BACKGROUND

### 1. Technical Field

The present disclosure relates to a display device and a method for fabricating the same.

### 2. Description of the Related Art

A head mounted display (HMD) is an image display device that may be worn on the head of a user, and a head mounted display may be in the form of glasses or a helmet to focus an image at a close distance in front of the eyes of the user. A head mounted display may implement virtual reality (VR) or augmented reality (AR).

A head mounted display may magnify an image displayed on a small display device by using a plurality of lenses, and the head mounted display may display the magnified image. Therefore, a display device applied to the head mounted display may provide high-resolution images, for example, images with a resolution of 3000 PPI (Pixels Per Inch) or higher. To this end, for some head mounted displays, an organic light emitting diode on silicon (OLEDoS), which is a high-resolution small organic light emitting display device, is used as the display device. The OLEDoS is an image display device in which an organic light emitting diode (OLED) is disposed on a semiconductor wafer substrate on which a complementary metal oxide semiconductor (CMOS) is disposed.

### SUMMARY

Aspects of the present disclosure provide a display device having a fine trench and a method for fabricating the same.

According to an embodiment of the disclosure, a display device comprising: a substrate; a transistor on the substrate; an interlayer insulating layer on the transistor; a first electrode disposed on the interlayer insulating layer, and connected to the transistor through a contact hole in the interlayer insulating layer; a pixel defining layer disposed on the interlayer insulating layer and the first electrode, where the pixel defining layer includes a first sub-pixel defining layer and a second sub-pixel defining layer spaced apart from each other; a sacrificial layer disposed in a groove of the interlayer insulating layer; a gap fill layer disposed on the sacrificial layer, between the first sub-pixel defining layer and the second sub-pixel defining layer; a light emitting stack on the first electrode and the pixel defining layer; and a first trench formed between the first sub-pixel defining layer and the gap fill layer, between an inner wall of the groove of the interlayer insulating layer and the gap fill layer, and between the inner wall of the groove and the sacrificial layer.

In an embodiment, the first trench has a groove shape continuously formed between the first sub-pixel defining layer and the gap fill layer, between the inner wall of the groove and the gap fill layer, and between the inner wall of the groove and the sacrificial layer.

In an embodiment, the light emitting stack is at least partially disconnected in an area corresponding to the first trench.

In an embodiment, a width of the first trench is 0.1 μm, and a depth of the first trench is 3000 Å.

In an embodiment, further comprising a second trench formed between the second sub-pixel defining layer and the gap fill layer, between another inner wall of the groove and the gap fill layer, and between the other inner wall of the groove and the sacrificial layer.

In an embodiment, the second trench has a groove shape continuously formed between the second sub-pixel defining layer and the gap fill layer, between the other inner wall of the groove and the gap fill layer, and between the other inner wall of the groove and the sacrificial layer.

In an embodiment, the light emitting stack is disconnected in an area corresponding to the second trench.

In an embodiment, a width of the second trench is 0.1 μm, and a depth of the second trench is 3000 Å.

In an embodiment, a top surface of the pixel defining layer is disposed at a height equal to a height of a top surface of the gap fill layer.

In an embodiment, the sacrificial layer comprises at least one of indium gallium zinc oxide (IGZO) or molybdenum (Mo).

In an embodiment, the gap fill layer comprises silicon oxide (SiOx).

In an embodiment, further comprising a second electrode on the light emitting stack.

According to an embodiment of the disclosure, a method for fabricating a display device, comprising: disposing an interlayer insulating layer on a substrate; disposing a first electrode on the interlayer insulating layer; disposing a pixel defining layer on the interlayer insulating layer and the first electrode; forming a preliminary trench having a groove in the interlayer insulating layer and forming a through hole in the pixel defining layer; disposing a sacrificial layer on the first electrode, the pixel defining layer, and an inner wall of the preliminary trench; disposing a gap fill layer on the sacrificial layer; removing the gap fill layer on the pixel defining layer and removing the sacrificial layer on the pixel defining layer such that the sacrificial layer remains on the first electrode, the gap fill layer remains on the first electrode, the gap fill layer remains in the preliminary trench, and the sacrificial layer remains in the preliminary trench; disposing a photoresist pattern covering the sacrificial layer in the preliminary trench, the gap fill layer in the preliminary trench, and one or more portions of the sacrificial layer adjacent to the pixel defining layer; removing the gap fill layer on the first electrode using the photoresist pattern as a mask; removing the photoresist pattern; and forming a first trench and a second trench by, using the gap fill layer in the preliminary trench as a mask, removing a remaining portion of the sacrificial layer except for a portion of the sacrificial layer covered by the gap fill layer.

In an embodiment, further comprising disposing a light emitting stack on the first electrode and the pixel defining layer.

In an embodiment, forming the first trench and the second trench disconnects the light emitting stack in areas corresponding to the first trench and the second trench.

In an embodiment, forming the preliminary trench separates the pixel defining layer into a first sub-pixel defining layer and a second sub-pixel defining layer spaced apart from each other by the preliminary trench.

In an embodiment, a top surface of the pixel defining layer is disposed at a height equal to a height of a top surface of the gap fill layer in the trench.

In an embodiment, the sacrificial layer comprises at least one of indium gallium zinc oxide (IGZO) or molybdenum (Mo).

In an embodiment, the gap fill layer comprises silicon oxide (SiOx).

In an embodiment, further comprising disposing a second electrode on the light emitting stack.

In an embodiment, a width of the first trench is 0.1 μm, and a depth of the first trench is 3000 Å, and wherein a width of the second trench is 0.1 μm, and a depth of the second trench is 3000 Å.

Embodiments of a display device and a method for fabricating the same as described herein support implementing a fine trench. For example, according to an embodiment, a chemical mechanical polishing method and thickness control of a sacrificial layer described herein supports forming a fine trench having a width of 100 nm, which is impossible to be implemented using a conventional photolithography process.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an exploded perspective view showing a display device according to an embodiment;

FIG. 2 is a layout diagram illustrating an example of the display panel shown in FIG. 1;

FIG. 3 is a block diagram illustrating a display device according to an embodiment;

FIG. 4 is an equivalent circuit diagram of a first sub-pixel according to an example embodiment;

FIGS. 5 and 6 are plan views illustrating pixels of a display area according to an embodiment;

FIG. 7 is a cross-sectional view illustrating an example of the display device taken along line A-A′ of FIG. 5;

FIG. 8 is a cross-sectional view of a display device according to an embodiment;

FIGS. 9 to 19 are cross-sectional process views of a display device according to an embodiment;

FIG. 20 is a diagram for describing the degree of disconnection of a light emitting stack ES according to the width of a fine trench;

FIG. 21 is a perspective view illustrating a head mounted display device according to an embodiment;

FIG. 22 is an exploded perspective view illustrating an example of the head mounted display device of FIG. 21; and

FIG. 23 is a perspective view illustrating a head mounted display device according to an embodiment.

### DETAILED DESCRIPTION

Embodiments supported by the present disclosure will now be described more fully hereinafter with reference to the accompanying drawings, in which one or more example embodiments are shown. Aspects supported by the present disclosure may, however, be embodied in different forms and should not be construed as limited to the embodiments set forth herein. Rather, these example embodiments are provided such that this disclosure will be thorough and complete, and will fully convey the scope of example aspects of the invention to those skilled in the art.

It will also be understood that when a layer is referred to as being “on” another layer or substrate, the layer can be directly on the other layer or substrate, or intervening layers may also be present. The same reference numbers indicate the same components throughout the specification. In the attached figures, the thickness of layers and regions is exaggerated for clarity.

Although the terms “first”, “second”, and the like may be used herein to describe various elements, these elements, should not be limited by these terms. These terms may be used to distinguish one element from another element. Thus, a first element discussed below may be termed a second element without departing from teachings of one or more embodiments. The description of an element as a “first” element is not limited to requiring and does not necessarily imply the presence of a second element or other elements. The terms “first”, “second”, and the like may also be used herein to differentiate different categories or sets of elements. For conciseness, the terms “first”, “second”, and the like may represent “first-category (or first-set)”, “second-category (or second-set)”, and the like, respectively.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially equal,” as used herein, means approximately or actually equal (e.g., within a threshold percent of equal).

The term “substantially the same,” as used herein, means approximately or actually the same (e.g., within a threshold difference amount).

Features of various embodiments of the present disclosure may be combined partially or totally. As will be clearly appreciated by those skilled in the art, technically various interactions and operations are possible. Various embodiments can be practiced individually or in combination.

Hereinafter, embodiments will be described in detail with reference to the accompanying drawings.

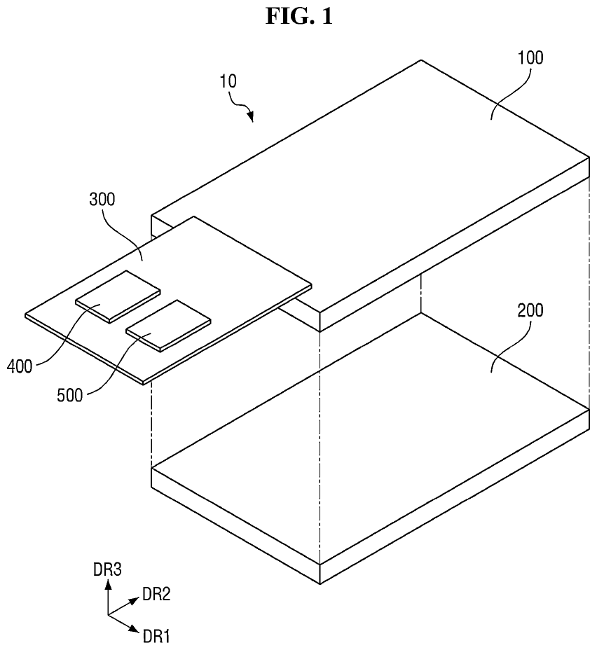

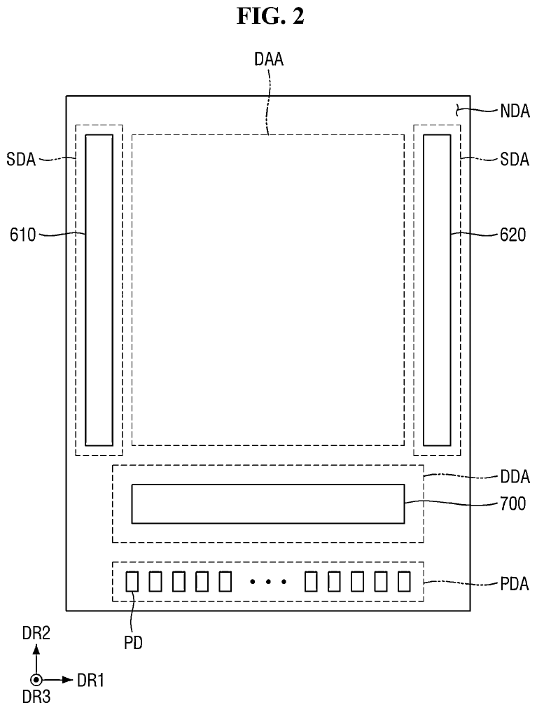

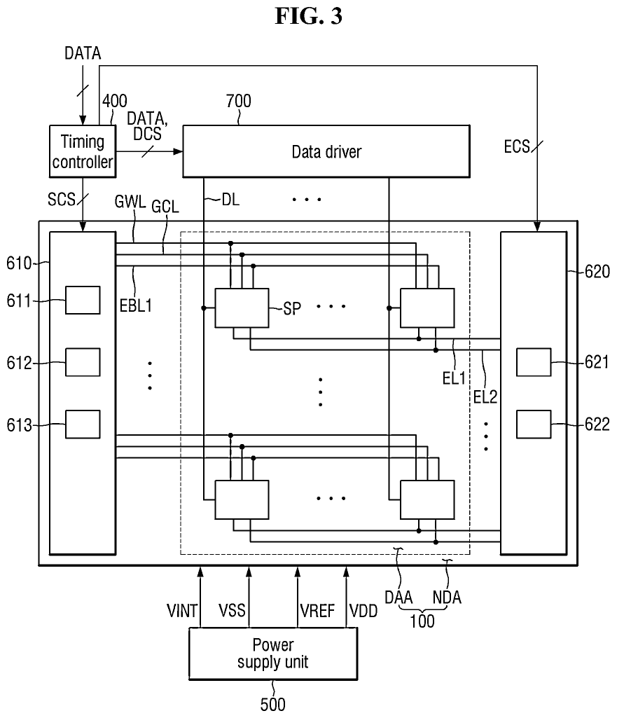

FIG. 1 is an exploded perspective view showing a display device according to an embodiment. FIG. 2 is a layout diagram illustrating an example of the display panel shown in FIG. 1. FIG. 3 is a block diagram illustrating a display device according to an embodiment.

Referring to FIGS. 1 and 2, a display device 10 according to an embodiment is a device displaying a moving image or a still image. The display device 10 according to an embodiment may be applied to portable electronic devices such as, for example, a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to an embodiment may be applied as a display unit of a television, a laptop, a monitor, a billboard, or an Internet-of-Things (IoT) terminal. Alternatively, or additionally, the display device 10 according to an embodiment may be applied to a smart watch, a watch phone, a head mounted display (HMD) for implementing virtual reality and augmented reality, and the like.

The display device 10 according to an embodiment includes a display panel 100, a heat dissipation layer 200, a circuit board 300, a driving circuit 400, and a power supply circuit 500.

The display panel 100 may have a planar shape such as, for example, a quadrilateral shape or a shape similar to a quadrilateral shape. For example, the display panel 100 may have a planar shape such as, for example, a quadrilateral shape, having a shorter side of a first direction DR1 and a longer side of a second direction DR2 crossing the first direction DR1. In the display panel 100, a corner where a shorter side in the first direction DR1 and a longer side in the second direction DR2 meet may be right-angled or rounded with a predetermined curvature. The planar shape of the display panel 100 is not limited to a quadrilateral shape, and may be another polygonal shape, a circular shape, or an elliptical shape. In some aspects, the planar shape may be, for example, a shape similar to another polygonal shape, a circular shape, or an elliptical shape. The planar shape of the display device 10 may conform to the planar shape of the display panel 100, but embodiments of the present disclosure are not limited thereto.

The display panel 100 includes a display area DAA displaying an image and a non-display area NDA not displaying an image as shown in FIG. 2.

The display area DAA includes a plurality of pixels PX, a plurality of scan lines SL, a plurality of emission control lines EL, and a plurality of data lines DL.

Each of the plurality of pixels PX includes a light emitting element that emits light. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

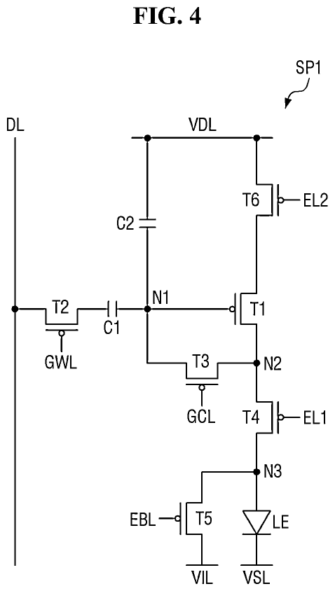

The plurality of pixels PX include a plurality of sub-pixels SP1, SP2, and SP3. The plurality of sub-pixels SP1, SP2, and SP3 may include a plurality of pixel transistors as shown in FIG. 4, and the plurality of pixel transistors may be formed by a semiconductor process and disposed on a semiconductor substrate SSUB (see FIG. 6). For example, the plurality of pixel transistors may be formed of a complementary metal oxide semiconductor (CMOS).

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first light emission control line EL1 among the plurality of first light emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light emitting element according to the data voltage.

The non-display area NDA includes a scan driving area SDA, a data driving area DDA, and a pad area PDA.

The scan driving area SDA may be an area in which a scan driver 610 and an emission driver 620 are disposed. Although the example in FIG. 2 illustrates that the scan driver 610 is disposed on the left side of the display area DAA and the emission driver 620 is disposed on the right side of the display area DAA, embodiments of the present disclosure are not limited thereto. For example, the scan driver 610 and the emission driver 620 may be disposed on both the left side and the right side of the display area DAA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (sec FIG. 6) through a semiconductor process. For example, the plurality of scan transistors and the plurality of light emitting transistors may be formed of a CMOS.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from a timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines EBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to first emission control lines EL1. The second emission control driver 622 may generate second emission control signals according to the emission timing control signal ECS and sequentially output them to second emission control lines EL2.

The data driving area DDA may be an area in which a data driver 700 is disposed. The data driver 700 may include a plurality of data transistors, and the plurality of data transistors may be formed on the semiconductor substrate SSUB (see FIG. 6) through a semiconductor process. For example, the plurality of data transistors may be formed of a CMOS.

The data driver 700 may receive the digital video data DATA and the data timing control signal DCS from the timing control circuit 400. The data driver 700 converts the digital video data DATA into analog data voltages according to the data timing control signal DCS and outputs the analog data voltages to data lines DL. In this case, the sub-pixels SP1, SP2, and SP3 are selected by the write scan signal of the scan driver 610, and data voltages may be supplied to the selected sub-pixels SP1, SP2, and SP3.

The pad area PDA includes a plurality of pads PD arranged in the first direction DR1. Each of the plurality of pads PD may be exposed, in that each of the plurality of pads PD is not covered by a cover layer CVL (see FIG. 6) and a polarizing plate POL (see FIG. 6).

The heat dissipation layer 200 may overlap the display panel 100 in a third direction DR3, which is the thickness direction of the display panel 100. The heat dissipation layer 200 may be disposed on one surface of the display panel 100, for example, on the rear surface of the display panel 100. The heat dissipation layer 200 serves to dissipate heat generated from the display panel 100. The heat dissipation layer 200 may include a metal layer such as, for example, graphite, silver (Ag), copper (Cu), or aluminum (Al) having high thermal conductivity.

The circuit board 300 may be electrically connected to the plurality of pads PD in the pad area PDA of the display panel 100 by using a conductive adhesive member such as, for example, an anisotropic conductive film. The circuit board 300 may be a flexible printed circuit board with a flexible material, or a flexible film. Although the circuit board 300 is illustrated in FIG. 1 as being unfolded, the circuit board 300 may be bent. For an example case in which the circuit board 300 is in a bent state, one end of the circuit board 300 may be disposed on the rear surface of the display panel 100. The one end of the circuit board 300 may be an end opposite to the other end of the circuit board 300 that is connected to the plurality of pads PD of the pad area PDA of the display panel 100 by using a conductive adhesive member.

The timing control circuit 400 may receive digital video data and timing signals inputted from the outside. The timing control circuit 400 may generate the scan timing control signal SCS, the emission timing control signal ECS, and a data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. Description of the first driving voltage VSS, the second driving voltage VDD, and the third driving voltage VINT will be provided later with reference to FIG. 4.

Each of the timing control circuit 400 and the power supply circuit 500 may be formed as an integrated circuit (IC) and attached to one side of the circuit board 300. The scan timing control signal SCS, the emission timing control signal ECS, the digital video data DATA, and the data timing control signal DCS of the timing control circuit 400 may be supplied to the display panel 100 through the circuit board 300. The first driving voltage VSS, the second driving voltage VDD, and the third driving voltage VINT of the power supply circuit 500 may be supplied to the display panel 100 through the circuit board 300.

In one or more alternative and/or additional embodiments, the timing control circuit 400 may be disposed in a timing circuit area of the non-display area NDA of the display panel 100, similarly to the scan driver 610, the emission driver 620, and the data driver 700. In this case, for example, the timing circuit area may be disposed between the data driving area DDA and the pad area PDA.

FIG. 4 is an equivalent circuit diagram of a first sub-pixel according to an example embodiment.

Referring to FIG. 4, the first sub-pixel SP1 may be connected to the write scan line GWL, the control scan line GCL, the bias scan line EBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 may include a plurality of transistors T1 to T6, a light emitting element LE, a first capacitor C1, and a second capacitor C2.

The light emitting element LE emits light in response to a driving current Ids flowing through the channel of the first transistor T1. The amount of light emitted by the light emitting element LE may be proportional to the driving current Ids. The light emitting clement LE may be disposed between the fourth transistor T4 and the first driving voltage line VSL. The first electrode of the light emitting element LE may be connected to the drain electrode of the fourth transistor T4, and the second electrode of the light emitting element LE may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but embodiments of the present disclosure are not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor TI may be a driving transistor that controls a source-drain current Ids (hereinafter referred to as a “driving current”) flowing between the source electrode and the drain electrode of the first transistor T1 according to a voltage applied to the gate electrode of the first transistor T1. The first transistor T1 includes a gate electrode connected to the first node N1, a source electrode connected to the drain electrode of the sixth transistor T6, and a drain electrode connected to a second node N2.

The second transistor T2 may be disposed between one electrode of the first capacitor C1 and the data line DL. The second transistor T2 is turned on by the write scan signal of the write scan line GWL to connect the one electrode of the first capacitor C1 to the data line DL. Accordingly, the data voltage of the data line DL may be applied to the one electrode of the first capacitor C1. The second transistor T2 includes a gate electrode connected to the write scan line GWL, a source electrode connected to the data line DL, and a drain electrode connected to the one electrode of the first capacitor C1.

The third transistor T3 may be disposed between the first node N1 and the second node N2. The third transistor T3 is turned on by the write control signal of the write control line GCL to connect the first node N1 to the second node N2. For this reason, since the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor ST4 is turned on by the first emission control signal of the first emission control line ELI to connect the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and a drain electrode connected to the third node N3.

The fifth transistor T5 may be disposed between the third node N3 and the third driving voltage line VIL. The fifth transistor T5 is turned on by the bias scan signal of the bias scan line EBL to connect the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is formed between the gate electrode of the first transistor T1 and the second driving voltage line VDL. The second capacitor C2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor C1, and the one electrode of the second capacitor C2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but embodiments of the present disclosure are not limited thereto. Each of the first to sixth transistors T1 to T6 may be an N-type MOSFET. In one or more alternative and/or additional embodiments, some of the first to sixth transistors T1 to T6 may be P-type MOSFETs, and each of the remaining transistors may be an N-type MOSFET.

Although the example in FIG. 4 illustrates that the first sub-pixel SP1 includes six transistors T1 to T6 and two capacitors C1 and C2, it should be noted that the equivalent circuit diagram of the first sub-pixel SP1 is not limited to the example shown in FIG. 4. For example, the number of transistors and the number of capacitors of the first sub-pixel SP1 are not limited to those shown in FIG. 4.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 4. Therefore, the description of the equivalent circuit diagram of the second sub-pixel SP2 and the equivalent circuit diagram of the third sub-pixel SP3 are omitted in the present disclosure.

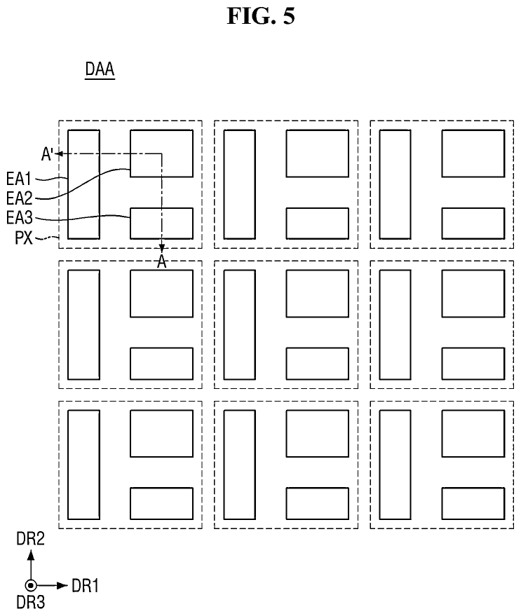

FIGS. 5 and 6 are plan views illustrating pixels of a display area according to an embodiment.

Referring to FIGS. 5 and 6, each of the pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

Each of the first emission area EA1, the second emission area EA2, and the third emission area EA3 may have, in a plan view, a quadrilateral shape such as, for example, a rectangle, a square, or a diamond. For example, as shown in FIG. 5A, the first emission area EA1 may have a rectangular shape, in a plan view, having a shorter side in the first direction DR1 and a longer side in the second direction DR2. In some aspects, as shown in FIG. 5, each of the second emission area EA2 and the third emission area EA3 may have a rectangular shape, in a plan view, having a longer side in the first direction DR1 and a shorter side in the second direction DR2.

In an example, the length of the first emission area EA1 in the first direction DR1 may be smaller than the length of the second emission area EA2 in the first direction DR1, and the length of the first emission area EA1 in the first direction DR1 may be smaller than the length of the third emission area EA3 in the first direction DR1. In some aspects, the length of the second emission area EA2 in the first direction DR1 and the length of the third emission area EA3 in the first direction DR1 may be substantially the same.

The length of the first emission area EA1 in the second direction DR2 may be larger than the sum of the length of the second emission area EA1 in the second direction DR2 and the length of third emission areas EA3 in the second direction DR2. The length of the second emission area EA2 in the second direction DR2 may be smaller than the length of the third emission area EA3 in the second direction DR2. In some embodiments, as illustrated at FIG. 5, the length of the second emission area EA2 in the second direction DR2 may be larger than the length of the third emission area EA3 in the second direction DR2.

Although the example in FIG. 5 illustrates that each of the first emission area EA1, the second emission area EA2, and the third emission area EA3 has a rectangular shape in a plan view, embodiments of the present disclosure are not limited thereto. For example, each of the first emission area EA1, the second emission area EA2, and the third emission area EA3 may have a polygonal shape other than a quadrilateral shape, a circular shape, or an elliptical shape in a plan view.

In each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In some aspects, the second emission area EA2 and the third emission area EA3 may be adjacent to each other in the second direction DR2. The area of the first emission area EA1, the area of the second emission area EA2, and the area of the third emission area EA3 may be different.

In one or more alternative and/or additional embodiments, as shown in FIG. 6, the first emission area EA1, the second emission area EA2, and the third emission area EA3 may have a hexagonal shape in a plan view. In this case, the first emission area EA1 and the second emission area EA2 may be adjacent to each other in the first direction DR1. However, the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may refer to a direction inclined by 45 degrees with respect to the first direction DR1 and the second direction DR2, between the first direction DR1 and the second direction DR2. The diagonal direction DD2 may be a direction perpendicular to the first diagonal direction DD1.

The first emission area EA1 may emit light of a first color, the second emission area EA2 may emit light of a second color, and the third emission area EA3 may emit light of a third color. In an example, the light of the first color may be light of a blue wavelength band, the light of the second color may be light of a green wavelength band, and the light of the third color may be light of a red wavelength band. For example, the blue wavelength band may be a wavelength band of light having a main peak wavelength in the range of about 370 nm to about 460 nm, the green wavelength band may be a wavelength band of light having a main peak wavelength in the range of about 480 nm to about 560 nm, and the red wavelength band may be a wavelength band of light having a main peak wavelength in the range of about 600 nm to about 750 nm.

In the example illustrated at FIG. 5, each of the plurality of pixels PX includes three emission areas EA1, EA2, and EA3, but embodiments of the present disclosure are not limited thereto. That is, for example, each of the plurality of pixels PX may include four emission areas.

The layout of the emission areas of the plurality of pixels PX is not limited to the example illustrated in FIG. 5. For example, the emission areas of the plurality of pixels PX may be arranged in a stripe structure in which the emission areas are arranged in the first direction DR1, a PenTile® structure in which the emission areas are arranged in a diamond shape, or a hexagonal structure in which the emission areas having, in a plan view, a hexagonal shape are arranged side by side as shown in FIG. 6.

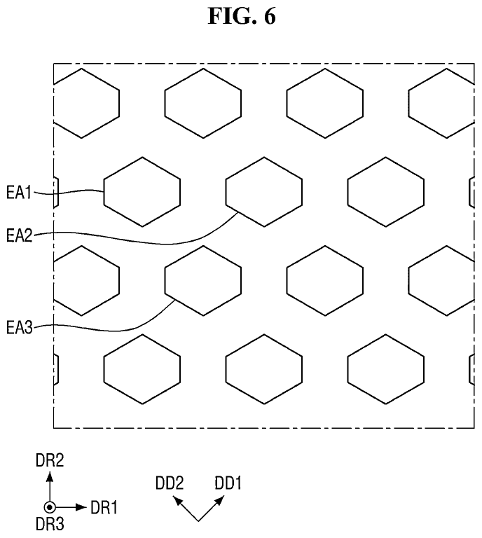

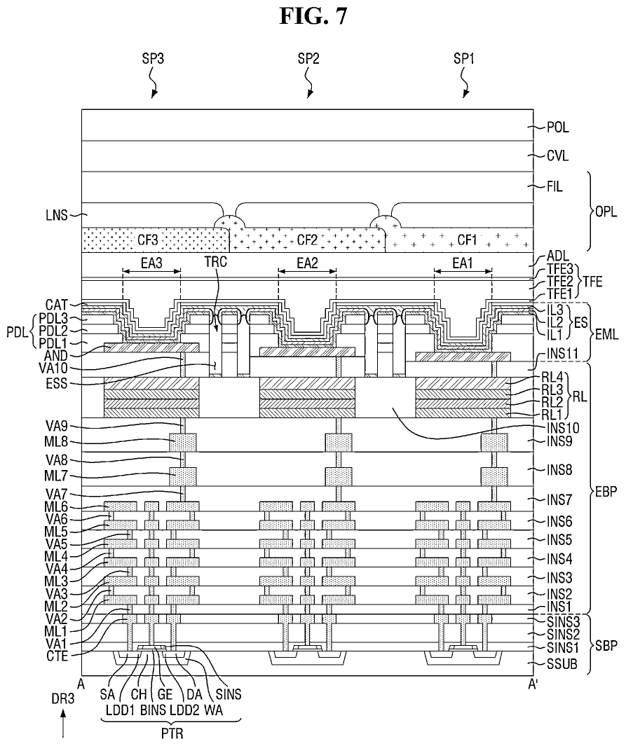

FIG. 7 is a cross-sectional view illustrating an example of the display device 10 taken along line A-A′ of FIG. 5.

Referring to FIG. 7, the display panel 100 includes a semiconductor backplane SBP, a light emitting element backplane EBP, a light emitting element layer EML, an encapsulation layer TFE, an optical layer OPL, the cover layer CVL, and a polarizing plate POL.

The semiconductor backplane SBP includes the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity (also referred to herein as an impurity of a first type). A plurality of well regions WA may be disposed on the top surface of the semiconductor substrate SSUB. The plurality of well regions WA may be regions doped with a second type impurity (also referred to herein as an impurity of a second type). The second type impurity may be different from the aforementioned first type impurity. For example, when the first type impurity is a p-type impurity, the second type impurity may be an n-type impurity. In one or more alternative and/or additional embodiments, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode of the pixel transistor PTR, and a channel region CH disposed between the source region SA and the drain region DA.

A lower insulating layer BINS may be disposed between the gate electrode GE and the well region WA. A side insulating layer SINS may be disposed on the side of the gate electrode GE. The side insulating layer SINS may be disposed on the lower insulating layer BINS.

Each of the source region SA and the drain region DA may be a region doped with the first type impurity. A gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region SA may be disposed on the other side of the gate electrode GE.

Each of the plurality of well regions WA further includes a first low-concentration impurity region LDD1 disposed between the channel region CH and the source region SA. Each of the plurality of well regions WA further includes a second low-concentration impurity region LDD2 disposed between the channel region CH and the drain region DA. The first low-concentration impurity region LDD1 may have a lower impurity concentration than the source region SA by (e.g., near or adjacent) the lower insulating layer BINS. The second low-concentration impurity region LDD2 may have a lower impurity concentration than the drain region DA by (e.g., near or adjacent) the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, which may prevent punch-through and hot carrier phenomena that could otherwise be caused by a short channel.

A first semiconductor insulating layer SINS1 may be disposed on the semiconductor substrate SSUB. The first semiconductor insulating layer SINS1 may be formed of silicon carbonitride (SiCN) or a silicon oxide (SiOx)-based inorganic layer, but embodiments of the present disclosure are not limited thereto.

A second semiconductor insulating layer SINS2 may be disposed on the first semiconductor insulating layer SINS1. The second semiconductor insulating layer SINS2 may be formed of a silicon oxide (SiOx)-based inorganic layer, but embodiments of the present disclosure are not limited thereto.

The plurality of contact terminals CTE may be disposed on the second semiconductor insulating layer SINS2. Each of the plurality of contact terminals CTE may be connected to any one of the gate electrode GE, the source region SA, and the drain region DA of each of the pixel transistors PTR through holes penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of copper (Cu), aluminum (Al), tungsten (W), molybdenum (Mo), chromium (Cr), gold (Au), titanium (Ti), nickel (Ni), and neodymium (Nd).

A third semiconductor insulating layer SINS3 may be disposed on a side surface (or multiple side surfaces) of each of the plurality of contact terminals CTE. The top surface of each of the plurality of contact terminals CTE may be exposed, in that the top surface of each of the plurality of contact terminals CTE is not covered by the third semiconductor insulating layer SINS3. The third semiconductor insulating layer SINS3 may be formed of a silicon oxide (SiOx)-based inorganic layer, but embodiments of the present disclosure are not limited thereto.

The semiconductor substrate SSUB may be replaced with a glass substrate or a polymer resin substrate such as, for example, polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP includes first to eighth metal layers ML1 to ML8, reflective metal layers RL1 to RL4, a plurality of vias VA1 to VA10, and a step layer STPL. In some aspects, the light emitting element backplane EBP includes a plurality of interlayer insulating layers INS1 to INS10 disposed between the first to sixth metal layers ML1 to ML6.

The first to eighth metal layers ML1 to ML8 serve to connect the plurality of contact terminals CTE exposed from the semiconductor backplane SBP to thereby implement the circuit of the first sub-pixel SP1 shown in FIG. 4. That is, the first to sixth transistors T1 to T6 are formed on the semiconductor backplane SBP, and the connection of the first to sixth transistors T1 to T6 and the first and second capacitors C1 and C2 is accomplished through the first to eighth metal layers ML1 to ML8. In some aspects, the connection between the drain region corresponding to the drain electrode of the fourth transistor T4, the source region corresponding to the source electrode of the fifth transistor T5, and the first electrode of the light emitting element LE is also accomplished through the first to eighth metal layers ML1 to ML8.

The first interlayer insulating layer INS1 may be disposed on the semiconductor backplane SBP. Each of the first vias VA1 may penetrate the first interlayer insulating layer INS1 and be connected to the contact terminal CTE exposed from the semiconductor backplane SBP. Each of the first metal layers ML1 may be disposed on the first interlayer insulating layer INS1 and may be connected to the first via VA1.

The second interlayer insulating layer INS2 may be disposed on the first interlayer insulating layer INS1 and the first metal layers ML1. Each of the second vias VA2 may penetrate the second interlayer insulating layer INS2 and be connected to the exposed first metal layer ML1. Each of the second metal layers ML2 may be disposed on the second interlayer insulating layer INS2 and may be connected to the second via VA2.

The third interlayer insulating layer INS3 may be disposed on the second interlayer insulating layer INS2 and the second metal layers ML2. Each of the third vias VA3 may penetrate the third interlayer insulating layer INS3 and be connected to the exposed second metal layer ML2. Each of the third metal layers ML3 may be disposed on the third interlayer insulating layer INS3 and may be connected to the third via VA3.

A fourth interlayer insulating layer INS4 may be disposed on the third interlayer insulating layer INS3 and the third metal layers ML3. Each of the fourth vias VA4 may penetrate the fourth interlayer insulating layer INS4 and be connected to the exposed third metal layer ML3. Each of the fourth metal layers ML4 may be disposed on the fourth interlayer insulating layer INS4 and may be connected to the fourth via VA4.

A fifth interlayer insulating layer INS5 may be disposed on the fourth interlayer insulating layer INS4 and the fourth metal layers ML4. Each of the fifth vias VA5 may penetrate the fifth interlayer insulating layer INS5 and be connected to the exposed fourth metal layer ML4. Each of the fifth metal layers ML5 may be disposed on the fifth interlayer insulating layer INS5 and may be connected to the fifth via VA5.

A sixth interlayer insulating layer INS6 may be disposed on the fifth interlayer insulating layer INS5 and the fifth metal layers ML5. Each of the sixth vias VA6 may penetrate the sixth interlayer insulating layer INS6 and be connected to the exposed fifth metal layer ML5. Each of the sixth metal layers ML6 may be disposed on the sixth interlayer insulating layer INS6 and may be connected to the sixth via VA6.

A seventh interlayer insulating layer INS7 may be disposed on the sixth interlayer insulating layer INS6 and the sixth metal layers ML6. Each of the seventh vias VA7 may penetrate the seventh interlayer insulating layer INS7 and be connected to the exposed sixth metal layer ML6. Each of the seventh metal layers ML7 may be disposed on the seventh interlayer insulating layer INS7 and may be connected to the seventh via VA7.

An eighth interlayer insulating layer INS8 may be disposed on the seventh interlayer insulating layer INS7 and the seventh metal layers ML7. Each of the eighth vias VA8 may penetrate the eighth interlayer insulating layer INS8 and be connected to the exposed seventh metal layer ML7. Each of the eighth metal layers ML8 may be disposed on the eighth interlayer insulating layer INS8 and may be connected to the eighth via VA8.

The first to eighth metal layers ML1 to ML8 and the first to eighth vias VA1 to VA8 may be formed of substantially the same material. The first to eighth metal layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of copper (Cu), aluminum (Al), tungsten (W), molybdenum (Mo), chromium (Cr), gold (Au), titanium (Ti), nickel (Ni), and neodymium (Nd). The first to eighth vias VA1 to VA8 may be formed of substantially the same material. First to eighth interlayer insulating layers INS1 to INS8 may be formed of a silicon oxide (SiOx)-based inorganic layer, but embodiments of the present disclosure are not limited thereto.

The thicknesses of the first metal layer ML1, the second metal layer ML2, the third metal layer ML3, the fourth metal layer ML4, the fifth metal layer ML5, and the sixth metal layer ML6 may be larger than the thicknesses of the first via VA1, the second via VA2, the third via VA3, the fourth via VA4, the fifth via VA5, and the sixth via VA6, respectively. The thickness of each of the second metal layer ML2, the third metal layer ML3, the fourth metal layer ML4, the fifth metal layer ML5, and the sixth metal layer ML6 may be larger than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same. For example, the thickness of the first metal layer ML1 may be approximately 1360 Å, the thickness of each of the second metal layer ML2, the third metal layer ML3, the fourth metal layer ML4, the fifth metal layer ML5, and the sixth metal layer ML6 may be approximately 1440 Å, and the thickness of each of the first via VA1, the second via VA2, the third via VA3, the fourth via VA4, the fifth via VA5, and the sixth via VA6 may be approximately 1150 Å.

The thickness of each of the seventh metal layer ML7 and the eighth metal layer ML8 may be larger than the thickness of each of the first metal layer ML1, the thickness of the second metal layer ML2, the thickness of the third metal layer ML3, the thickness of the fourth metal layer ML4, the thickness of the fifth metal layer ML5, and the sixth metal layer ML6. The thickness of the seventh metal layer ML7 and the thickness of the eighth metal layer ML8 may be larger than the thickness of the seventh via VA7 and the thickness of the eighth via VA8, respectively. The thickness of each of the seventh via VA7 and the eighth via VA8 may be larger than the thickness of each of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same. For example, the thickness of each of the seventh metal layer ML7 and the eighth metal layer ML8 may be approximately 9000 Å. The thickness of each of the seventh via VA7 and the eighth via VA8 may be approximately 6000 Å.

A ninth interlayer insulating layer INS9 may be disposed on the eighth interlayer insulating layer INS8 and the eighth metal layers ML8. The ninth insulating layer INS9 may be formed of a silicon oxide (SiOx)-based inorganic layer, but embodiments of the present disclosure are not limited thereto.

Each of the ninth vias VA9 may penetrate the ninth interlayer insulating layer INS9 and be connected to the exposed eighth metal layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of copper (Cu), aluminum (Al), tungsten (W), molybdenum (Mo), chromium (Cr), gold (Au), titanium (Ti), nickel (Ni), and neodymium (Nd). The thickness of the ninth via VA9 may be approximately 16500 Å.

A reflective electrode layer RL may be disposed on the ninth interlayer insulating layer INS9. The reflective electrode layer RL may include one or more of the first to fourth reflective electrodes RL1, RL2, RL3, and RL4. For example, the reflective electrode RL may include the first to fourth reflective electrodes RL1, RL2, RL3, and RLA as shown in FIG. 6.

Each of the first reflective electrodes RL1 may be disposed on the ninth interlayer insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of copper (Cu), aluminum (Al), tungsten (W), molybdenum (Mo), chromium (Cr), gold (Au), titanium (Ti), nickel (Ni), and neodymium (Nd). For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of copper (Cu), aluminum (Al), tungsten (W), molybdenum (Mo), chromium (Cr), gold (Au), titanium (Ti), nickel (Ni), and neodymium (Nd). For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of copper (Cu), aluminum (Al), tungsten (W), molybdenum (Mo), chromium (Cr), gold (Au), titanium (Ti), nickel (Ni), and neodymium (Nd). For example, the third reflective electrodes RL3 may include titanium nitride (TiN).

The fourth reflective electrodes RL4 may be respectively disposed on the third reflective electrodes RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of copper (Cu), aluminum (Al), tungsten (W), molybdenum (Mo), chromium (Cr), gold (Au), titanium (Ti), nickel (Ni), and neodymium (Nd). For example, the fourth reflective electrodes RL4 may include titanium (Ti).

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be 850 Å.

The tenth interlayer insulating layer INS10 may be disposed on the ninth interlayer insulating layer INS9. The tenth insulating layer INS10 may be formed of a silicon oxide (SiOx)-based inorganic layer, but embodiments of the present disclosure are not limited thereto.

The eleventh interlayer insulating layer INS11 may be disposed on the tenth interlayer insulating layer INS10 and the reflective electrode layer RL. The eleventh insulating layer INS11 may be formed of a silicon oxide (SiOx)-based inorganic layer, but embodiments of the present disclosure are not limited thereto.

The thickness of the eleventh interlayer insulator INS11 may vary in the first sub-pixel SP1, the second sub-pixel SP2, and the third sub-pixel SP3. The variance of the thickness of the eleventh interlayer insulator INS11 may adjust a resonance distance of light emitted from the light emitting elements LE in at least one of the first sub-pixel SP1, the second sub-pixel SP2, or the third sub-pixel SP3. That is, in order to adjust a distance from the reflective electrode layer RL to the second electrode CAT according to a main wavelength of light emitted from each of the first sub-pixel SP1, the second sub-pixel SP2, and the third sub-pixel SP3, the thickness of the eleventh interlayer insulating layer INS11 may be set for each of the first sub-pixel SP1, the second sub-pixel SP2, and the third sub-pixel SP3. For example, FIG. 7 illustrates that the distance between the first electrode AND and the reflective electrode layer RL in the third sub-pixel SP3 is larger than the distance between the first electrode AND and the reflective electrode layer RL in the second sub-pixel SP2 and the distance between the first electrode AND and the reflective electrode layer RL in the first sub-pixel SP1. In the example illustrated at FIG. 7, the distance between the first electrode AND and the reflective electrode layer RL in the second sub-pixel SP2 is larger than the distance between the first electrode AND and the reflective electrode layer RL in the first sub-pixel SP1.

Each of the tenth vias VA10 may penetrate the eleventh interlayer insulating layer INS11 and be connected to the exposed ninth metal layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of copper (Cu), aluminum (Al), tungsten (W), molybdenum (Mo), chromium (Cr), gold (Au), titanium (Ti), nickel (Ni), and neodymium (Nd). The thickness of the tenth via VA10 in the first sub-pixel SP1 may be less than the thickness of the tenth via VA10 in each of the second sub-pixel SP2 and the third sub-pixel SP3. The thickness of the tenth via VA10 in the second sub-pixel SP2 may be less than the thickness of the tenth via VA10 in the third sub-pixel SP3.

The light emitting element layer EML may be disposed on the light emitting element backplane EBP. The light emitting element layer EML may include the light emitting elements LE each having the first electrode AND, a light emitting stack ES, the intermediate layer IL, and the second electrode CAT, a pixel defining layer PDL, and a plurality of trenches TRC.

The first electrode AND of each of the light emitting elements LE may be disposed on the tenth interlayer insulating layer INS10 and connected to the tenth via VA10. The first electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth metal layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of copper (Cu), aluminum (Al), tungsten (W), molybdenum (Mo), chromium (Cr), gold (Au), titanium (Ti), nickel (Ni), and neodymium (Nd). For example, the first electrode AND of each of the light emitting elements LE may be titanium nitride (TiN).

The pixel defining layer PDL may be disposed on a part of the first electrode AND of each of the light emitting elements LE. The pixel defining layer PDL may cover the edge of the first electrode AND of each of the light emitting elements LE. The pixel defining layer PDL may serve to partition the first emission areas EA1, the second emission areas EA2, and the third emission areas EA3.

The first emission area EA1 may be defined as an area in which the first electrode AND, the light emitting stack ES, and the second electrode CAT are sequentially stacked in the first sub-pixel SP1 to emit light. The second emission area EA2 may be defined as an area in which the first electrode AND, the light emitting stack ES, and the second electrode CAT are sequentially stacked in the second sub-pixel SP2 to emit light. The third emission area EA3 may be defined as an area in which the first electrode AND, the light emitting stack ES, and the second electrode CAT are sequentially stacked in the third sub-pixel SP3 to emit light.

The pixel defining layer PDL may include first to third pixel defining layers PDL1, PDL2, and PDL3. The first pixel defining layer PDL1 may be disposed on the edge of the first electrode AND of each of the light emitting elements LE, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed of a silicon oxide (SiOx)-based inorganic layer, but embodiments of the present disclosure are not limited thereto. The first pixel defining layer PDL1, the second pixel defining layer PDL2, and the third pixel defining layer PDL3 may each have a thickness of about 500 Å.

When the first pixel defining layer PDL1, the second pixel defining layer PDL2, and the third pixel defining layer PDL3 are formed as one pixel defining layer, the height of the one pixel defining layer may increase, and thus the first encapsulation inorganic layer TFE1 may be separated due to step coverage. Step coverage refers to the ratio of the degree of thin film coated on an inclined portion to the degree of thin film coated on a flat portion. In some cases, as the step coverage decreases, the likelihood of the thin film being separated at the inclined portion increases.

Therefore, in order to prevent the first encapsulation inorganic layer TFE1 from being separated due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be larger than the width of the second pixel defining layer PDL2 and the width of the third pixel defining layer PDL3. The width of the second pixel defining layer PDL2 may be larger than the width of the third pixel defining layer PDL3. The width of the first pixel defining layer PDL1 refers to the horizontal length of the first pixel defining layer PDL1 defined in the first direction DR1 and the second direction DR2.

Each of the plurality of trenches TRC may penetrate the first pixel defining layer PDL1, the second pixel defining layer PDL2, and the third pixel defining layer PDL3. The eleventh interlayer insulating layer INS11 may be partially recessed at each of the plurality of trenches TRC.

At least one trench TRC may be disposed between adjacent sub-pixels SP1, SP2, and SP3. Although FIG. 7 illustrates that two trenches TRC are disposed between adjacent sub-pixels SP1, SP2, and SP3, embodiments of the present disclosure are not limited thereto.

The light emitting stack ES may include a plurality of intermediate layers. FIG. 7 illustrates that the light emitting stack ES has a three-tandem structure including a first intermediate layer IL1, a second intermediate layer IL2, and a third intermediate layer IL3, but embodiments of the present disclosure are not limited thereto. For example, the light emitting stack ES may have a two-tandem structure including two intermediate layers (e.g., first intermediate layer IL1 and second intermediate layer IL2, or the like).

In the three-tandem structure, the light emitting stack ES may have a tandem structure including the plurality of intermediate layers IL1, IL2, and IL3 that emit different light. For example, the light emitting stack ES may include the first intermediate layer IL1 that emits light of the first color, the second intermediate layer IL2 that emits light of the third color, and the third intermediate layer IL3 that emits light of the second color. The first intermediate layer IL1, the second intermediate layer IL2, and the third intermediate layer IL3 may be sequentially stacked.

The first intermediate layer IL1 may have a structure in which a first hole transport layer, a first organic light emitting layer that emits light of the first color, and a first electron transport layer are sequentially stacked. The second intermediate layer IL2 may have a structure in which a second hole transport layer, a second organic light emitting layer that emits light of the third color, and a second electron transport layer are sequentially stacked. The third intermediate layer IL3 may have a structure in which a third hole transport layer, a third organic light emitting layer that emits light of the second color, and a third electron transport layer are sequentially stacked.

A first charge generation layer for supplying charges to the second intermediate layer IL2 and supplying electrons to the first intermediate layer IL1 may be disposed between the first intermediate layer IL1 and the second intermediate layer IL2. The first charge generation layer may include an N-type charge generation layer that supplies electrons to the first intermediate layer IL1 and a P-type charge generation layer that supplies holes to the second intermediate layer IL2. The N-type charge generation layer may include a dopant of a metallic material.

A second charge generation layer for supplying charges to the third intermediate layer IL3 and supplying electrons to the second intermediate layer IL2 may be disposed between the second intermediate layer IL2 and the third intermediate layer IL3. The second charge generation layer may include an N-type charge generation layer that supplies electrons to the second intermediate layer IL2 and a P-type charge generation layer that supplies holes to the third intermediate layer IL3.

The first intermediate layer IL1 may be disposed on the first electrodes AND and the pixel defining layer PDL, and may be disposed on the bottom surface of each trench TRC. Due to the trenches TRC, the first intermediate layer IL1 may be separated between adjacent sub-pixels SP1, SP2, and SP3. For example, the trenches TRC may provide separation between sub-pixels SP1, SP2, and SP3. The second intermediate layer IL2 may be disposed on the first intermediate layer IL1. Due to the trenches TRC, the second intermediate layer IL2 may be separated between adjacent sub-pixels SP1, SP2, and SP3. A void or an empty space may be disposed between the first intermediate layer IL1 and the second intermediate layer IL2. The third intermediate layer IL3 may be disposed on the second intermediate layer IL2. The third intermediate layer IL3 may be disposed such that the third intermediate layer IL3 covers the second intermediate layer IL2 in each of the trenches TRC without being separated by the trench TRC. That is, in the three-tandem structure, each of the trenches TRC may be a structure for cutting off the first charge generation layer, the second charge generation layer, and the first and second intermediate layers IL1 and IL2 of the light emitting element layer EML between the adjacent sub-pixels SP1, SP2, and SP3. Additionally, in the two-tandem structure, each of the trenches TRC may be a structure for cutting off the charge generation layer disposed between a lower intermediate layer and an upper intermediate layer, and the lower intermediate layer.

In order to stably cut off the first and second intermediate layers IL1 and IL2 of the light emitting element layer EML between the adjacent sub-pixels SP1, SP2, and SP3 by the trenches TRC, the height of each trench TRC may be larger than the height of the pixel defining layer PDL. The height of each of the plurality of trenches TRC refers to the length of each of the plurality of trenches TRC in the third direction DR3. The height of the pixel defining layer PDL refers to the length of the pixel defining layer PDL in the third direction DR3. In some embodiments, in order to cut off the first to third intermediate layers IL1, IL2, and IL3 of the light emitting element layer EML between the neighboring sub-pixels SP1, SP2, and SP3, aspects of the present disclosure include implementing another structure instead of the trench TRC. For example, instead of the trench TRC, a reverse tapered partition wall may be disposed on the pixel defining layer PDL.

The number of the intermediate layers IL1, IL2, and IL3 that emit different light is not limited to the example shown in FIG. 7. For example, the light emitting stack ES may include two intermediate layers. In this case, one of the two intermediate layers may be substantially the same as the first intermediate layer IL1, and the other may include a second hole transport layer, a second organic light emitting layer, a third organic light emitting layer, and a second electron transport layer. In this case, a charge generation layer for supplying electrons to one intermediate layer and supplying charges to the other intermediate layer may be disposed between the two intermediate layers.

In the example illustrated at FIG. 7, the first to third intermediate layers IL1, IL2, and IL3 are all disposed in the first emission area EA1, the second emission area EA2, and the third emission area EA3, but embodiments of the present disclosure are not limited thereto. For example, the first intermediate layer IL1 may be disposed in the first emission area EA1 and may not be disposed in the second emission area EA2 and the third emission area EA3. In another example, the second intermediate layer IL2 may be disposed in the second emission area EA2 and may not be disposed in the first emission area EA1 and the third emission area EA3. In another example, the third intermediate layer IL3 may be disposed in the third emission area EA3 and may not be disposed in the first emission area EA1 and the second emission area EA2. In this example case, in which the first to third intermediate layers IL1, IL2, and IL3 are separately and respectively disposed in the first emission area EA1, the second emission area EA2, and the third emission area EA3, first to third color filters CF1, CF2, and CF3 of the optical layer OPL may be omitted.

The second electrode CAT may be disposed on the third intermediate layer IL3. The second electrode CAT may be disposed on the third intermediate layer IL3 in each of the plurality of trenches TRC. The second electrode CAT may be formed of a transparent conductive material (TCO) such as, for example, ITO or IZO that can transmit light or a semi-transmissive conductive material such as, for example, magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the light emitting element layer EML. The encapsulation layer TFE may include at least one inorganic layer TFE1 and TFE3 supportive of preventing oxygen or moisture from permeating into the light emitting element layer EML. In some aspects, the encapsulation layer TFE may include at least one organic layer supportive of protecting the light emitting element layer EML from foreign substances such as, for example, dust. For example, the encapsulation layer TFE may include a first encapsulation inorganic layer TFE1, an encapsulation organic layer TFE2, and a second encapsulation inorganic layer TFE3.

The first encapsulation inorganic layer TFE1 may be disposed on the second electrode CAT, the encapsulation organic layer TFE2 may be disposed on the first encapsulation inorganic layer TFE1, and the second encapsulation inorganic layer TFE3 may be disposed on the encapsulation organic layer TFE2. The first encapsulation inorganic layer TFE1 and the second encapsulation inorganic layer TFE3 may be formed of multiple layers in which one or more inorganic layers of silicon nitride (SiNx), silicon oxynitride (SiON), silicon oxide (SiOx), titanium oxide (TiOx), and aluminum oxide (AlOx) layers are alternately stacked. The encapsulation organic layer TFE2 may be a monomer. In one or more alternative and/or additional embodiments, the encapsulation organic layer TFE2 may be an organic layer such as, for example, acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In some aspects, the adhesive layer ADL may be a transparent adhesive member such as, for example, a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CFI may overlap the first emission area EA1 of the first sub-pixel SP1. The first color filter CF1 may transmit light of the first color, e.g., light of a blue wavelength band. The blue wavelength band may be approximately 370 nm to 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, e.g., light of a green wavelength band. The green wavelength band may be approximately 480 nm to 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, e.g., light of a red wavelength band. The red wavelength band may be approximately 600 nm to 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure that increases a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. In some aspects, the filling layer FIL may be a planarization layer. The filling layer FIL may be an organic layer such as, for example, acrylic resin, epoxy resin, phenolic resin, polyamide resin, or polyimide resin.

The cover layer CVL may be disposed on the filling layer FIL. The cover layer CVL may be a glass substrate or a polymer resin. In an example, the cover layer CVL is a glass substrate, and the cover layer CVL may be attached onto the filling layer FIL. In this case, the filling layer FIL may serve to bond the cover layer CVL. In another example, the cover layer CVL is a glass substrate, and the cover layer CVL may serve as an encapsulation substrate. When the cover layer CVL is a polymer resin, the cover layer CVL may be directly applied onto the filling layer FIL.

The polarizing plate may be disposed on one surface of the cover layer CVL. The polarizing plate may be a structure for preventing visibility degradation caused by reflection of external light. The polarizing plate may include a linear polarizing plate and a phase retardation film. For example, the phase retardation film may be a λ/4 plate (quarter-wave plate), but embodiments of the present disclosure are not limited thereto. In some examples, when visibility degradation caused by reflection of external light is sufficiently overcome by the first to third color filters CF1, CF2, and CF3, the polarizing plate may be omitted.

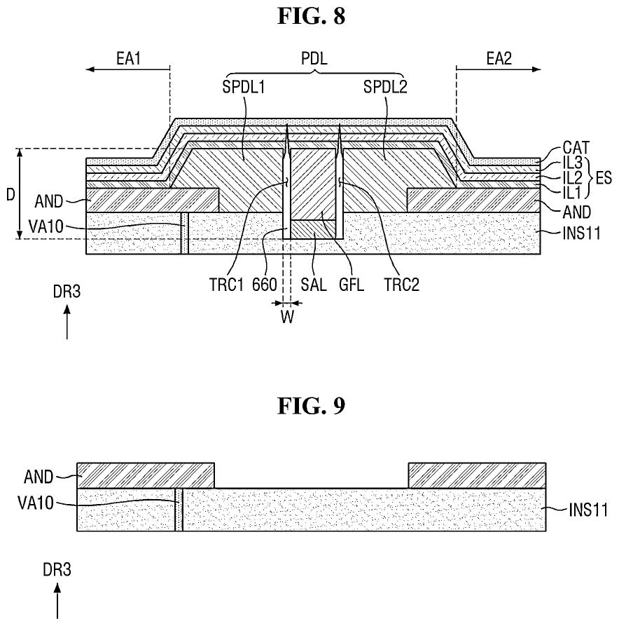

FIG. 8 is a cross-sectional view of a display device 10 according to an embodiment.

As shown in FIG. 8, the first electrode AND may be disposed on the eleventh interlayer insulating layer INS11. In some embodiments, as described herein, the first electrode AND may be connected to the underlying metal layer through the tenth via VA10.

The pixel defining layer PDL may be disposed on the first electrode AND and the eleventh interlayer insulating layer INS11. In an embodiment, the pixel defining layer PDL may include the first pixel defining layer PDL1, the second pixel defining layer PDL2, and the third pixel defining layer PDL3 that are sequentially stacked on the first electrode AND and the eleventh interlayer insulating layer INS11 in the third direction DR3 as described herein.

The pixel defining layer PDL may define the emission areas. For example, the pixel defining layer may have opening areas that define the first emission area EA1 and the second emission area EA2. In an embodiment, the pixel defining layer PDL may be at least partially disconnected. In this case, a left portion of the disconnected pixel defining layer PDL may be defined as a first sub-pixel defining layer SPDL1, and a right portion of the separated pixel defining layer PDL may be defined as a second sub-pixel defining layer SPDL2. The first sub-pixel defining layer SPDL1 may be spaced apart from the second sub-pixel defining layer SPDL2 by a predetermined distance.

A sacrificial layer SAL may be disposed in a groove 660 of the eleventh insulating layer INS11. The sacrificial layer SAL may include a metal material. For example, the sacrificial layer SAL may include at least one of indium gallium zinc oxide (IGZO) or molybdenum (Mo).

A gap fill layer GFL may be disposed on the sacrificial layer SAL. For example, the gap fill layer GFL may be disposed on the sacrificial layer SAL between the first sub-pixel defining layer SPDL1 and the second sub-pixel defining layer SPDL2. The gap fill layer GFL may include, for example, SiOx. In some embodiments, the height of the top surface of the gap fill layer GFL may be the same as the height of the top surface of the pixel defining layer PDL. In other words, the top surface of the gap fill layer GFL may be disposed at the same height as the top surface of the pixel defining layer PDL. In this case, for example, the heights described herein with reference to FIG. 8 may be the size in the third direction DR3.

A first trench TRC1 may be formed between the first sub-pixel defining layer SPDL1 and the gap fill layer GFL, between the gap fill layer GFL and the inner wall (e.g., left inner wall) of the groove 660 of the eleventh interlayer insulating layer INS11, and between the sacrificial layer SAL and the inner wall (e.g., left inner wall) of the groove 660 of the eleventh interlayer insulating layer INS11. In other words, the first trench TRC1 may have a groove shape continuously formed between the first sub-pixel defining layer SPDL1 and the gap fill layer GFL, between the gap fill layer GFL and the left inner wall of the groove 660 of the eleventh interlayer insulating layer INS11, and between the sacrificial layer SAL and the left inner wall of the groove 660 of the eleventh interlayer insulating layer INS11. The inner wall of the first trench TRC1 may be defined by the sacrificial layer SAL, the gap fill layer GFL, the first sub-pixel defining layer SPDL1, and the eleventh interlayer insulating layer INS11. The first trench TRC1 may have a fine size. For example, a width W of the first trench TRC1 may be 0.1 μm, and a depth D of the first trench TRC1 may be 3000 Å. In an embodiment, the first trench TRC1 may have a closed curve shape surrounding the emission area in a plan view. For example, the first trench TRC1 may have the closed curve shape surrounding the first emission area EA1 shown in FIG. 6 and may have the same shape as the first emission area EA1. In other words, the first trench TRC1 may have a larger size such that the first trench TRC1 surrounds the first emission area EA1 while having the same shape as the first emission area EA1 (e.g., a hexagonal closed curve shape as shown in FIG. 6).

A second trench TRC2 may be formed between the second sub-pixel defining layer SPDL2 and the gap fill layer GFL, between the gap fill layer GFL and the inner wall (e.g., right inner wall) of the groove 660 of the eleventh interlayer insulating layer INS11, and between the sacrificial layer SAL and the inner wall (e.g., right inner wall) of the groove 660 of the eleventh interlayer insulating layer INS11. In other words, the second trench TRC2 may have a groove shape continuously formed between the second sub-pixel defining layer SPDL2 and the gap fill layer GFL, between the gap fill layer GFL and the right inner wall of the groove 660 of the eleventh interlayer insulating layer INS11, and between the sacrificial layer SAL and the right inner wall of the groove 660 of the eleventh interlayer insulating layer INS11. The inner wall of the second trench TRC2 may be defined by the sacrificial layer SAL, the gap fill layer GFL, the second sub-pixel defining layer SPDL2, and the eleventh interlayer insulating layer INS11. The second trench TRC2 may have a fine size. For example, the second trench TRC2 may have the same width and depth as the first trench TRC1. In other words, the width of the second trench TRC2 may be 0.1 μm, and the depth of the second trench TRC2 may be 3000 Å.

In an embodiment, the second trench TRC2 may have a closed curve shape surrounding the emission area in a plan view. For example, the second trench TRC2 may have the closed curve shape surrounding the first emission area EA1 shown in FIG. 6 and may have the same shape as the first emission area EA1. In other words, the second trench TRC2 may have a larger size such that the second trench TRC2 surrounds the first emission area EA1 while having the same shape as the first emission area EA1 (e.g., a hexagonal closed curve shape as shown in FIG. 6). In some embodiments, when the first trench TRC1 and the second trench TRC2 surround the same emission area (e.g., the first emission area EA1), the second trench TRC2 may have a larger size than the first trench TRC1 such that the second trench TRC2 surrounds the first emission area EA1 and the first trench TRC1 together.

In an embodiment, the second trench TRC2 may surround an emission area other than the emission area surrounded by the first trench TRC1. For example, when the first trench TRC1 has a closed curve shape surrounding the first emission area EA1, the second trench TRC2 may surround the second emission area EA2 adjacent to the first emission area EA1. In other words, the second trench TRC2 may have a larger size such that the second trench TRC2 surrounds the second emission area EA2 while having the same shape as the second emission area EA2 (e.g., a hexagonal closed curve shape as shown in FIG. 6).

The light emitting stack ES may be disposed on the first electrode AND and the pixel defining layer PDL. As described herein, the light emitting stack ES may include the first intermediate layer IL1, the second intermediate layer IL2, and the third intermediate layer IL3 that are sequentially disposed on the first electrode AND and the pixel defining layer PDL in the third direction DR3. In this case, the light emitting stack ES may be disconnected in the areas corresponding to the first trench TRC1 and the second trench TRC2 by the first trench TRC1 and the second trench TRC2. For example, each of the first intermediate layer IL1, the second intermediate layer IL2, and the third intermediate layer IL3 may be disconnected in the area corresponding to the first trench TRC1. Each of the first intermediate layer IL1, the second intermediate layer IL2, and the third intermediate layer IL3 may be disconnected in the area corresponding to the second trench TRC2. In some embodiments, when the light emitting stack ES further includes a charge generation layer disposed between the adjacent intermediate layers, the charge generation layer may also be disconnected. Accordingly, the example aspects of the light emitting stack ES may prevent leakage current (e.g., side leakage current) between the adjacent sub-pixels SP1, SP2, and SP3. Therefore, color mixture may be prevented between the adjacent sub-pixels SP1, SP2, and SP3.

The second electrode CAT may be disposed on the light emitting stack ES.

FIGS. 9 to 19 are cross-sectional process views of a display device according to an embodiment. Example aspects of a method and processes supported by aspects of the present disclosure are described with reference to FIG. 9. In the descriptions of the method and processes herein, the operations may be performed in a different order than the order shown and/or described, or the operations may be performed in different orders or at different times. Certain operations may also be left out of the flowcharts, one or more operations may be repeated, or other operations may be added.

As shown in FIG. 9, the method may include disposing the eleventh interlayer insulating layer INS11 having the tenth via VA10 on the substrate SSUB. Thereafter, the method may include disposing the first electrode AND on the eleventh interlayer insulating layer INS11.

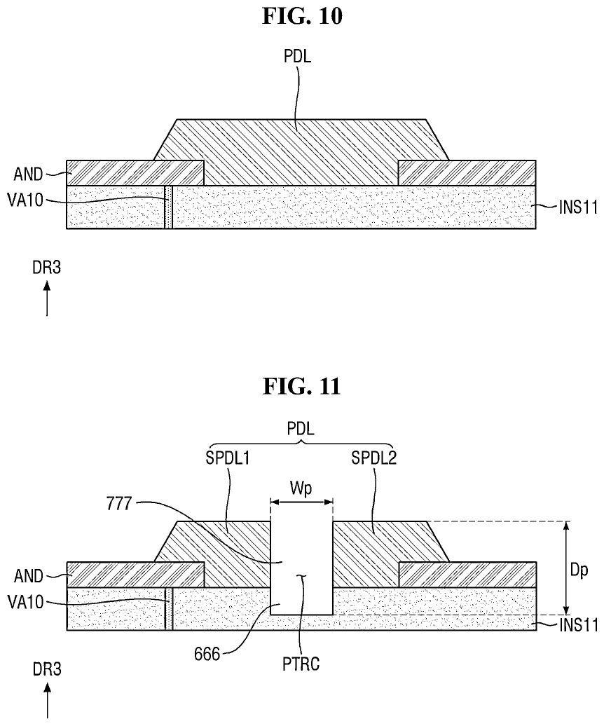

As shown in FIG. 10, the method may include disposing the pixel defining layer PDL on the eleventh interlayer insulating layer INS11 and the first electrode AND.

As shown in FIG. 11, the method may include forming a preliminary trench PTRC in the pixel defining layer PDL and the eleventh interlayer insulating layer INS11. The preliminary trench PTRC may penetrate the pixel defining layer PDL. In this case, the pixel defining layer PDL may be disconnected by the preliminary trench PTRC and separated into the first sub-pixel defining layer SPDL1 and the second sub-pixel defining layer SPDL2. For example, the forming of the preliminary trench PTRC may disconnect the pixel defining layer PDL. In some aspects, by the preliminary trench PTRC, a through hole 777 may be formed in the pixel defining layer PDL, and a groove 666 may be formed in the eleventh interlayer insulating layer INS11 below the pixel defining layer PDL. In other words, the preliminary trench PTRC may include the through hole 777 penetrating the pixel defining layer PDL and the groove 666 of the eleventh interlayer insulating layer INS11, and the through hole 777 may be connected to the groove 666. The inner wall of the preliminary trench PTRC may be defined by the eleventh interlayer insulating layer INS11, the first sub-pixel defining layer SPDL1, and the second sub-pixel defining layer SPDL2. In some embodiments, a width Wp of the preliminary trench PTRC may be 10 μm, and a depth Dp of the preliminary trench PTRC may be 3000 Å.

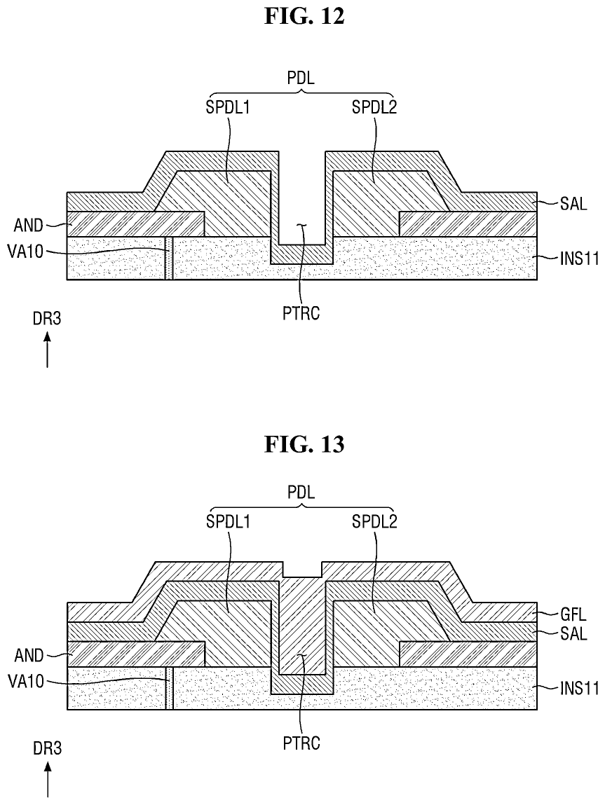

As shown in FIG. 12, the method may include forming the sacrificial layer SAL in the preliminary trench PTRC. For example, the method may include disposing the sacrificial layer SAL along the inner wall of the preliminary trench PTRC. In this case, the sacrificial layer SAL formed on the inner wall of the preliminary trench PTRC, which is parallel to the third direction DR3, may have a fine width. For example, a portion of the sacrificial layer SAL, which is formed on the inner wall of the preliminary trench PTRC, may have a width of 1000 Å. Here, the width may correspond to the width of the aforementioned first trench. Additionally, or alternatively, the method may include forming the aforementioned sacrificial layer SAL on the first electrode AND and the pixel defining layer PDL.

As shown in FIG. 13, the method may include disposing the gap fill layer GFL on the sacrificial layer SAL. In this case, a part of the gap fill layer GFL may be disposed in the preliminary trench PTRC.

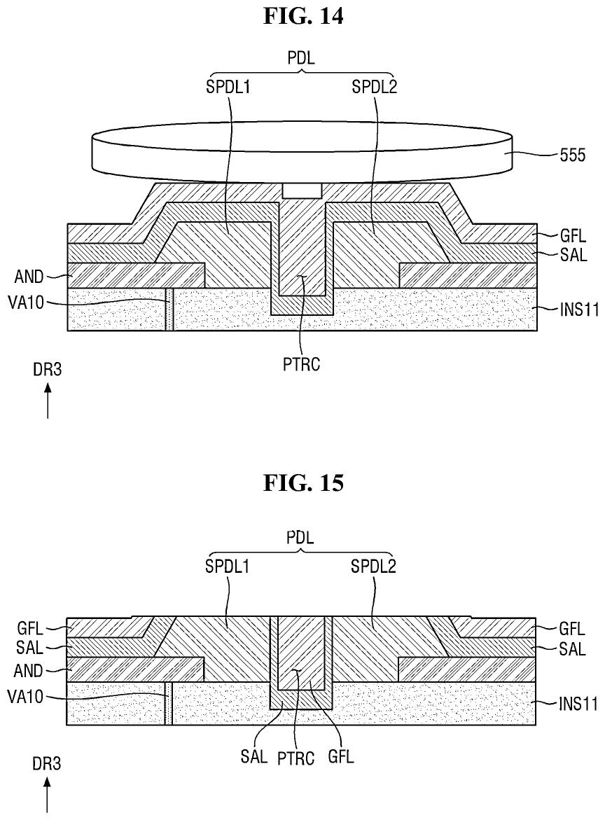

As shown in FIG. 14, the method may include planarizing the gap fill layer GFL and the sacrificial layer SAL. In other words, the gap fill layer GFL and the sacrificial layer SAL may be planarized with respect to the top surface of the pixel defining layer. For example, the method may include removing the gap fill layer GFL and the sacrificial layer SAL on the pixel defining layer PDL by a chemical mechanical polishing device 555.

As shown in FIG. 15, the method may include removing the gap fill layer GFL and the sacrificial layer SAL on the pixel defining layer PDL. In some embodiments, the sacrificial layer SAL and the gap fill layer GFL on the first electrode AND and the sacrificial layer SAL and the gap fill layer GFL in the preliminary trench PTRC may remain. In other words, by the chemical mechanical polishing process shown in FIG. 14, the gap fill layer GFL and the sacrificial layer SAL may be disposed on the first electrode AND and in the preliminary trench PTRC as shown in FIG. 15. In some embodiments, the method may include performing the chemical mechanical polishing process such that the height of the top surface of the pixel defining layer PDL becomes the same as the height of the gap fill layer GFL in the preliminary trench PTRC by the polishing process.

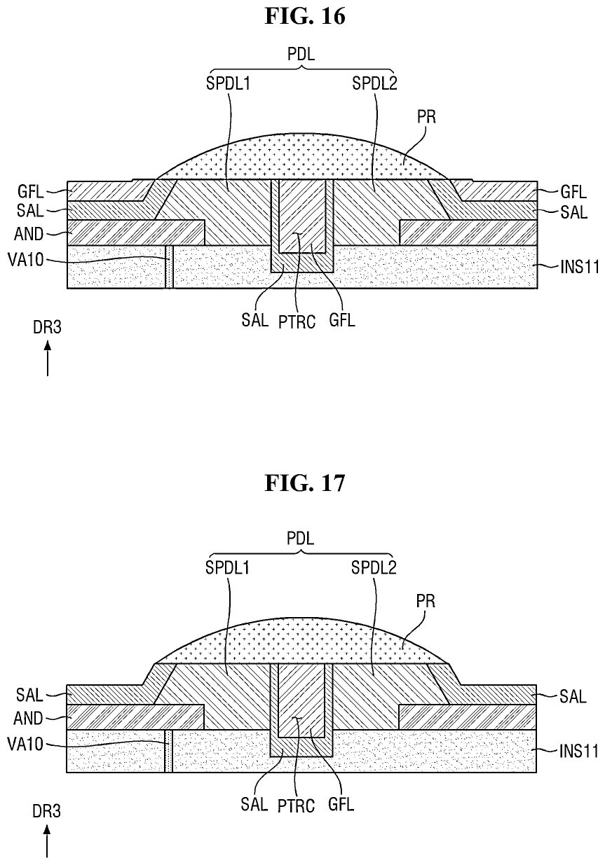

As shown in FIG. 16, the method may include disposing a photoresist pattern PR such that the photoresist pattern PR covers the sacrificial layer SAL and the gap fill layer GFL in the preliminary trench PTRC and one or more portions of the sacrificial layer SAL adjacent to the pixel defining layer PDL. In other words, the method may include disposing the photoresist pattern PR on the sacrificial layer SAL and the gap fill layer GFL in the preliminary trench PTRC, and on one or more portions of the sacrificial layer SAL adjacent to the pixel defining layer PDL.

In an example, when an etching process is performed using the photoresist pattern PR as a mask, the gap fill layer GFL that is not covered by the photoresist pattern PR may be removed as shown in FIG. 17. In other words, the gap fill layer GFL on the first electrode AND may be removed by the etching process described with reference to FIG. 17.

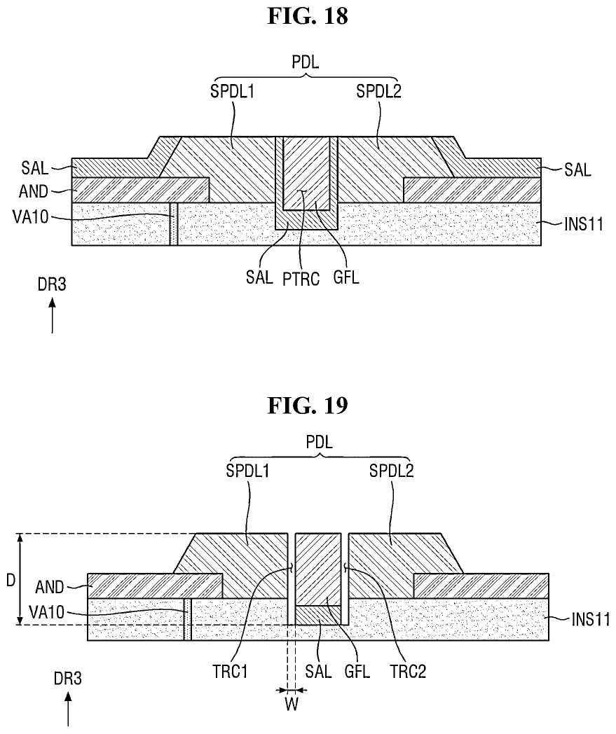

As shown in FIG. 18, the method may include removing the photoresist pattern PR. For example, the photoresist pattern PR may be removed by an ashing process.

As shown in FIG. 19, by performing the etching process using the gap fill layer GFL in the preliminary trench PTRC as a mask, the etching process may remove the remaining portion of the sacrificial layer SAL except for the sacrificial layer SAL covered by the gap fill layer GFL. By the etching process, the first trench TRC1 and the second trench TRC2 may be formed to have fine sizes. The inner wall of the first trench TRC1 may be defined by the sacrificial layer SAL, the gap fill layer GFL, the first sub-pixel defining layer SPDL1, and the eleventh interlayer insulating layer INS11. Additionally, the inner wall of the second trench TRC2 may be defined by the sacrificial layer SAL, the gap fill layer GFL, the second sub-pixel defining layer SPDL2, and the eleventh interlayer insulating layer INS11.

In some aspects, although not shown, the method may include disposing the light emitting stack ES on the first electrode AND and the pixel defining layer PDL. In this case, the light emitting stack ES may be disconnected in the areas corresponding to the first trench TRC1 and the second trench TRC2.

In some aspects, although not shown, the method may include disposing the second electrode CAT on the light emitting stack ES.

According to an embodiment, the thickness control of the sacrificial layer SAL and the chemical mechanical polishing method supports forming the fine trenches TRC1 and TRC2 having a width of 100 nm, which is impossible to be implemented by the conventional photolithography process.

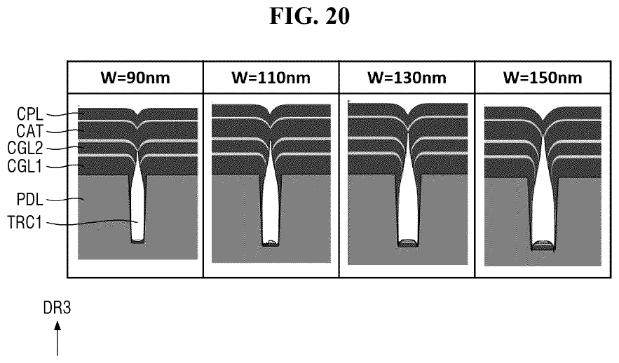

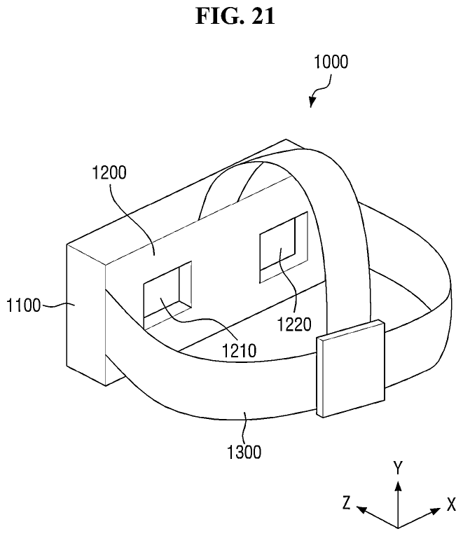

FIG. 20 is a diagram for describing the degree of disconnection of the light emitting stack ES according to the width of a fine trench.

As in the example shown in FIG. 20, increases in the width of the first trench TRC1 may result in disconnecting more charge generation layers GCL1 and GCL2 of the light emitting stack ES. For example, when the width of the first trench TRC1 is 90 nm, the first charge generation layer GCL1 may be disconnected. When the width of the first trench TRC1 is 110 nm, the first charge generation layer GCL1 and the second charge generation layer GCL2 disposed thereon may be disconnected. In some embodiments, when the width of the first trench TRC1 is 130 nm or 150 nm, the charge generation layers GCL1 and GCL2 may be disconnected and, in some cases, the second electrode CAT may be disconnected. According to some embodiments, the width of the first trench TRC1 may be preferably 110 nm.

In some embodiments, according to FIG. 20, the display device may further include a capping layer CPL disposed on the second electrode CAT. For example, the method may include disposing the capping layer CPL on the second electrode CAT.

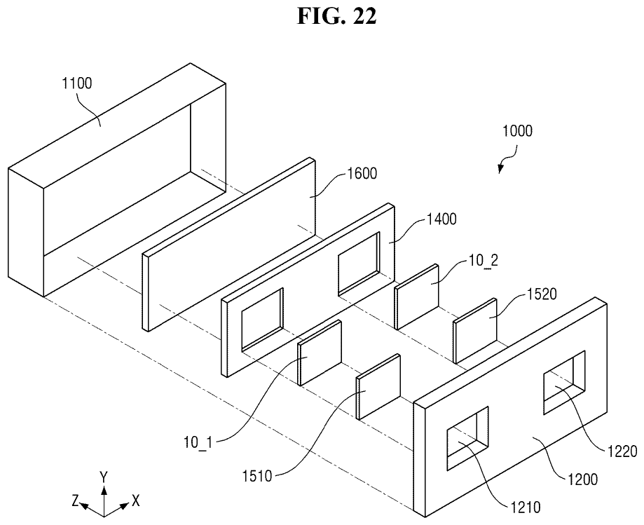

FIG. 21 is a perspective view illustrating a head mounted display device according to an embodiment. FIG. 22 is an exploded perspective view illustrating an example of the head mounted display device of FIG. 21.

Referring to FIGS. 21 and 22, a head mounted display device 1000 according to an embodiment includes a first display device 10_1, a second display device 10_2, a display device housing 1100, a housing cover 1200, a first eyepiece 1210, a second eyepiece 1220, a head mounted band 1300, a middle frame 1400, a first optical member 150, a second optical member 1520, and a control circuit board 1600.

The first display device 10_1 provides an image to the user's left eye, and the second display device 10_2 provides an image to the user's right eye. The first display device 10_1 and the second display device 10_2 include aspects of a display device 10 described herein, and repeated descriptions of like elements are omitted for brevity. For example, each of the first display device 10_1 and the second display device 10_2 may be substantially the same as the display device 10 described in conjunction with FIGS. 1 to 6, and repeated description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, or additionally, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed such that the housing cover 1200 covers one open surface of the display device housing 1100. The housing cover 1200 may include the first eyepiece 1210 at which the user's left eye is disposed and the second eyepiece 1220 at which the user's right eye is disposed. FIGS. 21 and 22 illustrate that the first eyepiece 1210 and the second eyepiece 1220 are disposed separately, but embodiments of the present disclosure are not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

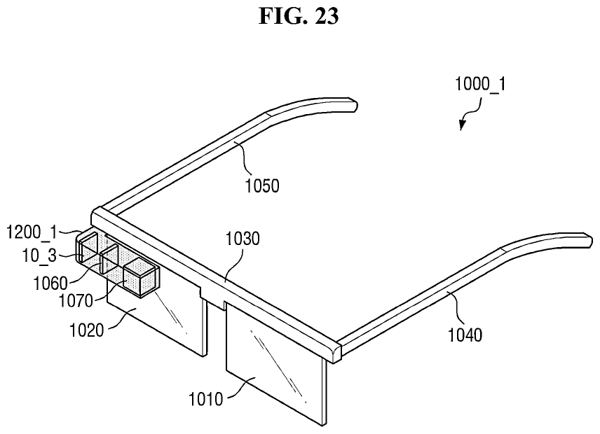

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1200 is implemented such that the display device housing 1200 is lightweight and compact, the head mounted display device 1000 may be provided with, as shown in FIG. 23, an eyeglass frame instead of the head mounted band 1300.

In some aspects, the head mounted display device 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 23 is a perspective view illustrating a head mounted display device according to an embodiment.

Referring to FIG. 23, a head mounted display device 1000_1 according to an embodiment may be an eyeglasses-type display device in which a display device housing 1200_1 is implemented in a lightweight and compact manner. The head mounted display device 1000_1 according to an embodiment may include a display device 10_3, a left eye lens 1010, a right eye lens 1020, a support frame 1030, temples 1040 and 1050, an optical member 1600, an optical path changing member 1070, and the display device housing 1200_1.

The display device housing 1200_1 may include the display device 10_3, the optical member 1600, and the optical path changing member 1070. The image displayed on the display device 10_3 may be magnified by the optical member 1600, and may be provided to the user's right eye through the right eye lens 1020 after the optical path of the right eye lens 1020 is changed by the optical path changing member 1070. As a result, the user may view an augmented reality image, through the right eye, in which a virtual image displayed on the display device 10_3 and a real image seen through the right eye lens 1020 are combined.

FIG. 23 illustrates that the display device housing 1200_1 is disposed at the end on the right side of the support frame 1030, but embodiments of the present disclosure are not limited thereto. For example, the display device housing 1200_1 may be disposed on the left end of the support frame 1030, and in this case, the image of the display device 10_3 may be provided to the user's left eye. In one or more alternative and/or additional embodiments, the display device housing 1200_1 may be disposed on both the left and right ends of the support frame 1030, and in this case, the user may view the image displayed on the display device 10_3 through both the left and right eyes.

Embodiments of the present disclosure support one or more processes (methods, flowcharts) supportive of the features and embodiments described herein. Descriptions that an element “may be disposed,” “may be formed,” and the like include processes (methods, flowcharts) for disposing, forming, positioning, modifying the element, and the like in accordance with example aspects described herein.

It will be able to be understood by one of ordinary skill in the art to which the present disclosure belongs that the present disclosure may be implemented in other specific forms without changing the technical spirit or essential features of the present disclosure. Therefore, it is to be understood that the example embodiments described herein are illustrative rather than being restrictive in all aspects. It is to be understood that the scope of the present disclosure are defined by the claims rather than the detailed description described herein and all modifications and alterations derived from the claims and their equivalents fall within the scope of the present disclosure.

What is claimed is:

1. A display device comprising:
a substrate;
a transistor on the substrate;
an interlayer insulating layer on the transistor;
a first electrode disposed on the interlayer insulating layer and connected to the transistor through a contact hole in the interlayer insulating layer;
a pixel defining layer disposed on the interlayer insulating layer and the first electrode, wherein the pixel defining layer comprises a first sub-pixel defining layer and a second sub-pixel defining layer spaced apart from each other;
a sacrificial layer disposed in a groove of the interlayer insulating layer;
a gap fill layer disposed on the sacrificial layer, between the first sub-pixel defining layer and the second sub-pixel defining layer;
a light emitting stack on the first electrode and the pixel defining layer; and
a first trench formed between the first sub-pixel defining layer and the gap fill layer, between an inner wall of the groove of the interlayer insulating layer and the gap fill layer, and between the inner wall of the groove and the sacrificial layer.

2. The display device of claim 1, wherein the first trench has a groove shape continuously formed between the first sub-pixel defining layer and the gap fill layer, between the inner wall of the groove and the gap fill layer, and between the inner wall of the groove and the sacrificial layer.

3. The display device of claim 1, wherein the light emitting stack is at least partially disconnected in an area corresponding to the first trench.

4. The display device of claim 1, further comprising a second trench formed between the second sub-pixel defining layer and the gap fill layer, between another inner wall of the groove and the gap fill layer, and between the other inner wall of the groove and the sacrificial layer.

5. The display device of claim 4, wherein the second trench has a groove shape continuously formed between the second sub-pixel defining layer and the gap fill layer, between the other inner wall of the groove and the gap fill layer, and between the other inner wall of the groove and the sacrificial layer.

6. The display device of claim 4, wherein the light emitting stack is disconnected in an area corresponding to the second trench.

7. The display device of claim 4, wherein a width of the first trench is 0.1 μm, and a depth of the first trench is 3000 Å, and wherein a width of the second trench is 0.1 μm, and a depth of the second trench is 3000 Å.

8. The display device of claim 1, wherein a top surface of the pixel defining layer is disposed at a height equal to a height of a top surface of the gap fill layer.

9. The display device of claim 1, wherein the sacrificial layer comprises at least one of indium gallium zinc oxide (IGZO) or molybdenum (Mo).

10. The display device of claim 1, wherein the gap fill layer comprises silicon oxide (SiOx).

11. The display device of claim 1, further comprising a second electrode on the light emitting stack.

12. A method for fabricating a display device, comprising:
disposing an interlayer insulating layer on a substrate;
disposing a first electrode on the interlayer insulating layer;
disposing a pixel defining layer on the interlayer insulating layer and the first electrode;
forming a preliminary trench having a groove in the interlayer insulating layer and forming a through hole in the pixel defining layer;
disposing a sacrificial layer on the first electrode, the pixel defining layer, and an inner wall of the preliminary trench;
disposing a gap fill layer on the sacrificial layer;
removing the gap fill layer on the pixel defining layer and removing the sacrificial layer on the pixel defining layer such that the sacrificial layer remains on the first electrode, the gap fill layer remains on the first electrode, the gap fill layer remains in the preliminary trench, and the sacrificial layer remains in the preliminary trench;
disposing a photoresist pattern covering the sacrificial layer in the preliminary trench, the gap fill layer in the preliminary trench, and one or more portions of the sacrificial layer adjacent to the pixel defining layer;
removing the gap fill layer on the first electrode using the photoresist pattern as a mask;
removing the photoresist pattern; and
forming a first trench and a second trench by, using the gap fill layer in the preliminary trench as a mask, removing a remaining portion of the sacrificial layer except for a portion of the sacrificial layer covered by the gap fill layer.

13. The method of claim 12, further comprising disposing a light emitting stack on the first electrode and the pixel defining layer.

14. The method of claim 13, wherein forming the first trench and the second trench disconnects the light emitting stack in areas corresponding to the first trench and the second trench.

15. The method of claim 13, further comprising disposing a second electrode on the light emitting stack.

16. The method of claim 12, wherein forming the preliminary trench separates the pixel defining layer into a first sub-pixel defining layer and a second sub-pixel defining layer spaced apart from each other by the preliminary trench.

17. The method of claim 12, wherein a top surface of the pixel defining layer is disposed at a height equal to a height of a top surface of the gap fill layer in the trench.

18. The method of claim 12, wherein the sacrificial layer comprises at least one of indium gallium zinc oxide (IGZO) or molybdenum (Mo).

19. The method of claim 12, wherein the gap fill layer comprises silicon oxide (SiOx).

20. The method of claim 12, wherein a width of the first trench is 0.1 μm, and a depth of the first trench is 3000 Å, and
wherein a width of the second trench is 0.1 μm, and a depth of the second trench is 3000 Å.
